(19) United States
(12) Patent Application Publication
(10) Pub. No.: US 2026/0101477 A1
(43) Pub. Date: Apr. 9, 2026

(54) DYNAMIC PHASE CHANGE MATERIAL FOR HEAT REMOVAL FROM ELECTRONIC DEVICES

(71) Applicant: Raytheon Company, Tewksbury, MA (US)

(72) Inventors: Yasmin Khakpour, South Windsor, CT (US); Gary S. Krenzul, Holland, MA (US); Abbas A. Alahyari, Glastonbury, CT (US)

(21) Appl. No.: 18/909,501

(22) Filed: Oct. 8, 2024

(51) Int. Cl. H05K 7/20

(52) U.S. Cl. CPC H05K 7/20327

(57) ABSTRACT

A system is provided for heat transfer for an electronic device. The system includes a container, phase change material (PCM) at least partially filling the container in solid or liquid form, a screw disposed in the container and a drive element. The drive element is coupled with the screw and is configured to drive screw rotation to continuously and repetitively force the PCM in solid form through the container toward the electronic device whereupon electronic device heat liquifies proximal PCM and the PCM in liquid form along an exterior of the container away from the electronic device for PCM solidification.

### BACKGROUND

Exemplary embodiments of the present disclosure relate to heat removal from electronic devices and, more particularly, to dynamic phase change material (PCM) for heat removal from electronic devices.

A characteristic property of phase change materials (PCMs) is that PCMs have a high latent heat of fusion. This allows PCMs to store a large amount of energy with a low temperature increase. As such, PCMs tend to be a solution to certain challenges in dynamic thermal management. A problem exists, however, in that another characteristic property of PCMs is that their energy density and power density tend to decrease as a transient melt front moves away from a heat source.

### SUMMARY

According to an aspect of the disclosure, a system is provided for heat transfer for an electronic device. The system includes a container, phase change material (PCM) at least partially filling the container in solid or liquid form, a screw disposed in the container and a drive element. The drive element is coupled with the screw and is configured to drive screw rotation to continuously and repetitively force the PCM in solid form through the container toward the electronic device whereupon electronic device heat liquifies proximal PCM and the PCM in liquid form along an exterior of the container away from the electronic device for PCM solidification.

In accordance with additional and/or alternative embodiments, the container is cylindrical.

In accordance with additional and/or alternative embodiments, the exterior of the container includes one or more grooves through which the PCM in liquid form is forced away from the electronic device.

In accordance with additional and/or alternative embodiments, the one or more grooves extend along a longitudinal axis of the container.

In accordance with additional and/or alternative embodiments, a heating element is disposed in the one or more grooves to maintain the PCM in liquid form.

In accordance with additional and/or alternative embodiments, a copper wire is disposed in thermal contact with the electronic device and in the one or more grooves to maintain the PCM in liquid form.

In accordance with additional and/or alternative embodiments, at least one of the screw is a single, monolithic member rotated by the drive element and the screw includes a non-rotating portion and a rotating portion which extends through the non-rotating portion and which is rotated by the drive element.

According to an aspect of the disclosure, a system is provided for heat transfer for an electronic device. The system includes an outer container, an inner container disposed within the outer container, phase change material (PCM) overfilling the inner container and at least partially filling the outer container in solid or liquid form, a screw disposed in the inner container and a drive element. The drive element is coupled with the screw and is configured to drive screw rotation to continuously and repetitively force the PCM in solid form through the inner container toward the electronic device whereupon electronic device heat liquifies proximal PCM and the PCM in liquid form between the inner and outer containers away from the electronic device for PCM solidification.

In accordance with additional and/or alternative embodiments, the outer container and the inner container are cylindrical.

In accordance with additional and/or alternative embodiments, the inner container includes one or more grooves on an exterior surface thereof through which the PCM in liquid form is forced away from the electronic device.

In accordance with additional and/or alternative embodiments, the one or more grooves extend along a longitudinal axis of the inner container.

In accordance with additional and/or alternative embodiments, a heating element disposed in the one or more grooves to maintain the PCM in liquid form.

In accordance with additional and/or alternative embodiments, a copper wire is disposed in thermal contact with the electronic device and in the one or more grooves to maintain the PCM in liquid form.

In accordance with additional and/or alternative embodiments, at least one of the screw is a single, monolithic member rotated by the drive element and the screw includes a non-rotating portion and a rotating portion which extends through the non-rotating portion and which is rotated by the drive element.

According to an aspect of the disclosure, a system is provided for heat transfer for an electronic device. The system includes an outer container, which is cylindrical, an inner container, which is cylindrical and disposed within the outer container to define an annular space between the inner and outer containers, phase change material (PCM) overfilling the inner container and at least partially filling the outer container in solid or liquid form, a screw disposed in the inner container and a drive element. The drive element is coupled with the screw and is configured to drive screw rotation to continuously and repetitively force the PCM in solid form through the inner container toward the electronic device whereupon electronic device heat liquifies proximal PCM and the PCM in liquid form through the annular space away from the electronic device for PCM solidification.

In accordance with additional and/or alternative embodiments, the inner container includes one or more grooves on an exterior surface thereof through which the PCM in liquid form is forced away from the electronic device.

In accordance with additional and/or alternative embodiments, the one or more grooves extend along a longitudinal axis of the inner container.

In accordance with additional and/or alternative embodiments, a heating element is disposed in the one or more grooves to maintain the PCM in liquid form.

In accordance with additional and/or alternative embodiments, a copper wire is disposed in thermal contact with the electronic device and in the one or more grooves to maintain the PCM in liquid form.

In accordance with additional and/or alternative embodiments, at least one of the screw is a single, monolithic member rotated by the drive element and the screw includes a non-rotating portion and a rotating portion which extends through the non-rotating portion and which is rotated by the drive element.

Additional features and advantages are realized through the techniques of the present disclosure. Other embodiments and aspects of the disclosure are described in detail herein and are considered a part of the claimed technical concept. For a better understanding of the disclosure with the advantages and the features, refer to the description and to the drawings.

### BRIEF DESCRIPTION OF THE DRAWINGS

For a more complete understanding of this disclosure, reference is now made to the following brief description, taken in connection with the accompanying drawings and detailed description, wherein like reference numerals represent like parts:

FIGS. 1A and 1B are top-down and side views of a rotational system provided for heat transfer for an electronic device in accordance with embodiments;

FIGS. 2A and 2B are top-down and side views of a linear system provided for heat transfer for an electronic device in accordance with embodiments

FIGS. 3A and 3B are perspective and side views of a system provided for heat transfer for an electronic device with a single-phase spiral actuator in accordance with embodiments;

FIG. 4 is a perspective view of a dual-phase spiral actuator with first and second fins with opposing ramp curvature pitches for use in the system of FIGS. 3A and 3B in accordance with embodiments;

FIG. 5 is a perspective view of a dual-phase spiral actuator with multiple opposing screws for use in the system of FIGS. 3A and 3B in accordance with embodiments;

FIG. 6 is a perspective view of an axial-to-rotational movement mechanism for use in the system of FIGS. 3A and 3B and/or with the dual-phase spiral actuators of FIGS. 4 and 5 in accordance with embodiments;

FIG. 7 is a side view of a system provided for heat transfer for an electronic device with an outer container, an inner container and a screw/auger in accordance with embodiments;

FIGS. 8A and 8B are axial and side views of one or more grooves of the inner container of FIG. 7 in accordance with embodiments;

FIG. 9 is a perspective view of a heating element disposed in a groove of an inner container in accordance with embodiments;

FIG. 10 is a perspective view of a screw/auger that is monolithically rotatable in accordance with embodiments; and

FIG. 11 is a perspective view of a screw/auger that has non-rotating and rotating portions in accordance with embodiments.

### DETAILED DESCRIPTION

A detailed description of one or more embodiments of the disclosed apparatus and method are presented herein by way of exemplification and not limitation with reference to the Figures.

As computing capabilities improve and applications call on electronics and microelectronics for increasingly complex and computationally expensive operations, a power draw and heat rejection in electronic devices can become rate-limiting. Furthermore, many products operate under size, weight and power (SWaP) constraints that can limit available mitigation strategies for cooling sub-system designs. Low SWaP cooling strategies that can scale down to microelectronic applications, but that are also applicable in macro-scale electronics, will tend to increase product capabilities.

PCMs offer improved cooling capacity performance for small-planform applications that historically relied on heat sinks (sensible heat capacity of sink) or heat fins (sensible heat capacity of sink and nearby air). PCMs provide cooling via the latent heat of phase transformation, which can have orders of magnitude higher specific capacity than sensible heat capacity. Although PCMs offer a higher cooling capacity, PCMs can also suffer from poor performance due to melt-pool growth that increases the distance between a heat source and solid PCM thereby increasing the thermal resistance and hindering cooling performance.

Existing strategies to mitigate thermal resistance growth from melt-pools include the addition of more thermally conductive materials like carbon or metal powders. These strategies tend to add weight and volume to the PCM thus limiting its specific cooling capacity. In some cases, the problem of the increased thermal resistance of the liquid layer of the PCM has been addressed by using a piston in a casing filled with PCM to exert a downward force on the PCM toward a heating element. As the heating element heats and melts the PCM, the downward force exerted by the piston drives the liquid PCM outwardly and urges the remaining solid PCM downwardly toward the heating element. While this action is useful in continuing to present solid PCM to the heating element, it is not continuous or repeatable since, at the end of the piston stroke, the system must be reset.

Thus, as will be described below, a system for dynamic PCM usage is provided for heat removal from electronic devices in order to continuously maintain a thin liquid PCM layer proximate to a heating element. The system continuously and repeatedly replaces liquid PCM with solid PCM and thereby maintains a thermal resistance of the liquid layer at a certain level.

In exemplary cases, a linear or a rotating configuration is provided with PCM filled pockets that are initially in solid phase. In each case, the PCM filled pockets move as they exchange heat with a heat source and the PCM in the PCM filled pockets melts and becomes liquified. As the PCM pockets move, a solid pack of PCM comes in contact with the heat source and the old pack of PCM, which is now liquified, will solidify through a cooling process (i.e., through convection or cold plates) to be ready for the next turn. The moving can be powered by an electrical actuator such as a stepper motor or a PCB motor. In other exemplary cases, a spiral actuator or a dual spiral actuator replaces liquid PCM with solid PCM as the spiral actuator or the dual spiral actuator rotates. The rotation can be provided actively by a stepper type motor or passively using a shape-memory-alloy spring. The spring may be torsional or may use an axial-to-rotational movement mechanism. In yet another exemplary case, a screw is turned down to push melted and liquified PCM outwardly and away from a heat source. The liquid PCM passes through grooved sides of a container reaches the top of the container where it returns to the bottom, driven by the screw. A copper (or any thermally conductive) wire can be inserted in the grooved sides to prevent the solidification of the liquified PCM in the grooved sides by conducting heat from the heat source to the PCM. This ensures that the PCM is still in the liquid phase once it reaches the top of the container and solidifies while the screw is turned down.

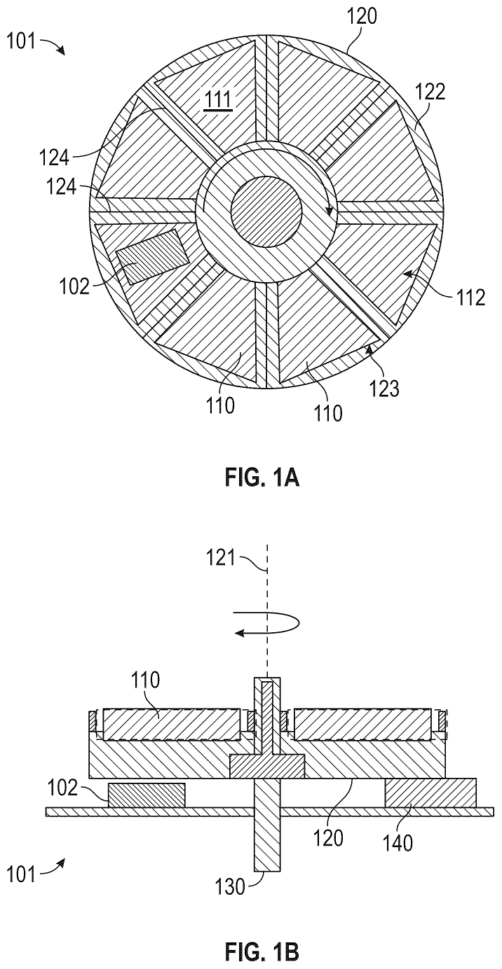

With reference to FIGS. 1A and 1B, a system 101 is provided for heat transfer for an electronic device 102. The system 101 includes packs 110 that are filled with PCM 111, an annular body 120 that is partially adjacent to the electronic device 102 and a drive element 130. The annular body 120 has a rotational axis 121 and includes a surface 122 on which the packs 110 are disposed in an annular arrangement 123 about the rotational axis 121. Each of the packs 110 can have a circular segment shape 112 and may, in some cases, include a membrane in which the PCM 111 is stored, where the membrane is non-porous with respect to the PCM 111. The annular body 120 can include insulating separation walls 124 that are annularly interleaved between neighboring ones of the packs 110.

The drive element 130 is coupled with the annular body 120 and is configured to drive a rotational movement of the annular body 120 in forward or reverse rotational directions about the rotational axis 121. This rotational movement of the annular body 120 sequentially brings one or more of the packs 110 into and then out of heat transfer proximity with the electronic device 102 for a heat transfer duration that is sufficient to melt at least a portion or all of the PCM 111 of the one or more of the packs 110 in a continuous and repetitive manner. The drive element 130 can include or be provided as at least one or more of a stepper motor and a printed circuit board (PCB) motor. In either case, the rotational movement of the annular body 120 can be one of discrete (i.e., the rotational movement rotates about the rotational axis 121 by a predetermined angular value, stops and restarts repeatedly) and continuous (i.e., the rotational movement rotates continuously about the rotational axis 121).

While the one or more of the packs 110 are sequentially brought into and then out of heat transfer proximity with the electronic device 102, other ones of the packs 110 are remote from the electronic device 102. Within these remote ones of the packs 110, the portion or all of the PCM 111 that has been melted cools and solidifies, thus making the remote ones of the packs 110 ready for their next exposure to the electronic device 102. The cooling and solidification of the PCM 111 of the remote ones of the packs 110 can be one of passive cooling and active cooling. In the passive cooling, the PCM 111 of the remote ones of the packs 110 radiates heat outwardly and/or conducts heat to ambient air/atmosphere. In the active cooling, the PCM 111 of the remote ones of the packs 110 radiates heat outwardly and/or conducts heat to ambient air/atmosphere and a coolant 140 can be provided to actively remove heat from the PCM 111.

The continuous and repetitive manner of the above-mentioned sequence is provided such that the rotational movement of the annular body 120 can continue indefinitely without pause or a need for a system reset with the one or more of the packs 110 being brought into and then out of the heat transfer proximity with the electronic device 102 for the heat transfer duration that is sufficient to melt the at least the portion or all of the PCM 111 of the one or more of the packs 110.

As used herein, the heat transfer proximity can be defined as a distance from the electronic device 102 to the one or more of the packs 110 at which heat of the electronic device 102 is transferred to and sufficient to melt the at least the portion or all of the PCM 111 of the one or more of the packs 110 during the time of the heat transfer duration. As used herein, the heat transfer duration can be a function of the speed of the rotational movement, the dimensions of the annular body 120 and the dimensions of the packs 110.

In accordance with embodiments, only a single one of the packs 110 may be brought into and then out of the heat transfer proximity for the heat transfer duration at a time.

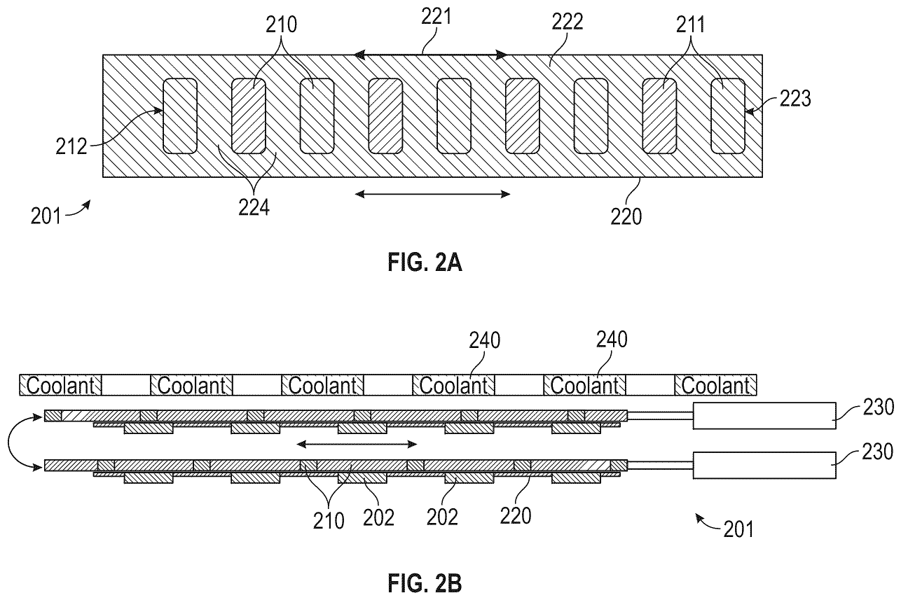

With reference to FIGS. 2A and 2B, a system 201 is provided for heat transfer for an electronic device 202. The system 201 includes packs 210 that are filled with PCM 211, a linear body 220 that is partially adjacent to the electronic device 202 and a drive element 230. The linear body 220 has a longitudinal axis 221 and includes a surface 222 on which the packs 210 are disposed in a linear arrangement 223 along the longitudinal axis 221. Each of the packs 210 can have an elongate shape 212 and may, in some cases, include a membrane in which the PCM 211 is stored, where the membrane is non-porous with respect to the PCM 211. The linear body 220 can includes insulating separation walls 224 that are linearly interleaved between neighboring ones of the packs 210.

The drive element 230 is coupled with the linear body 220 and is configured to drive a linear movement of the linear body 120 in forward or reverse rotational directions along the longitudinal axis 221. This linear movement of the linear body 220 sequentially brings one or more of the packs 110 into and then out of heat transfer proximity with the electronic device 202 for a heat transfer duration that is sufficient to melt at least a portion or all of the PCM 211 of the one or more of the packs 210 in a continuous and repetitive manner. The drive element 230 can include or be provided as at least one or more of a stepper motor and a printed circuit board (PCB) motor. In either case, the linear movement of the linear body 220 can be one of discrete (i.e., the linear movement moves along the longitudinal axis 221 by a predetermined distance, stops and restarts repeatedly) and continuous (i.e., the linear movement moves continuously along the longitudinal axis 221).

While the one or more of the packs 210 are sequentially brought into and then out of heat transfer proximity with the electronic device 202, other ones of the packs 210 are remote from the electronic device 202. Within these remote ones of the packs 210, the portion or all of the PCM 211 that has been melted cools and solidifies, thus making the remote ones of the packs 210 ready for their next exposure to the electronic device 202. The cooling and solidification of the PCM 211 of the remote ones of the packs 210 can be one of passive cooling and active cooling. In the passive cooling, the PCM 211 of the remote ones of the packs 210 radiates heat outwardly and/or conducts heat to ambient air/atmosphere. In the active cooling, the PCM 211 of the remote ones of the packs 210 radiates heat outwardly and/or conducts heat to ambient air/atmosphere and a coolant 240 can be provided to actively remove heat from the PCM 211.

The continuous and repetitive manner of the above-mentioned sequence is provided such that the linear movement of the linear body 220 can continue indefinitely without pause or a need for a system reset with the one or more of the packs 210 being brought into and then out of the heat transfer proximity with the electronic device 202 for the heat transfer duration that is sufficient to melt the PCM 211 of the one or more of the packs 210.

As used herein, the heat transfer proximity can be defined as a distance from the electronic device 202 to the one or more of the packs 210 at which heat of the electronic device 202 is transferred to and sufficient to melt the at least the portion or all of the PCM 211 of the one or more of the packs 210 during the time of the heat transfer duration. As used herein, the heat transfer duration can be a function of the speed of the linear movement, the dimensions of the linear body 220 and the dimensions of the packs 210.

In accordance with embodiments, only a single one of the packs 210 may be brought into and then out of the heat transfer proximity for the heat transfer duration at a time.

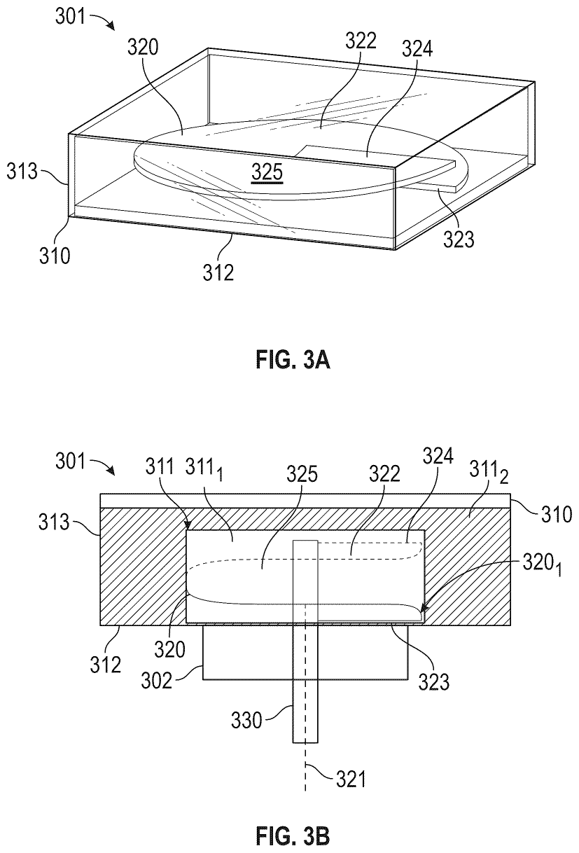

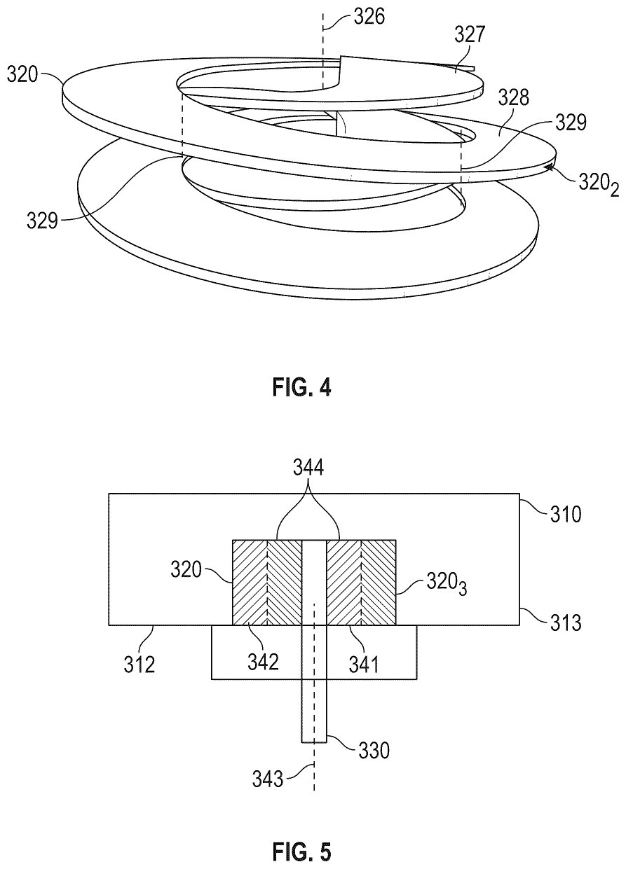

With reference to FIGS. 3A and 3B and to FIGS. 4-6, a system 301 is provided for heat transfer for an electronic device 302. The system 301 includes a container 310 that is partially adjacent to the electronic device 302, PCM 311 at least partially filling the container 310 in solid form or liquid form, a spiral actuator 320 that is disposed in the container 310 with the PCM 311 and a drive element 330. The container 310 can be block-shaped and can include a lower surface 312 that is adjacent to the electronic device 302 and sidewalls 313. In these or other cases, the spiral actuator 320 can be arranged proximate to the lower surface 312 in a center of the container 310. The drive element 330 is coupled with the spiral actuator 320 and is configured to drive rotation of the spiral actuator 320 to continuously and repetitively force corresponding movements of the portion 311₁ of the PCM 311 that is in solid form and the portion 311₂ of the PCM 311 that is in liquid form. That is, the rotation of the spiral actuator 320 continuously and repetitively forces the portion 311₁ of the PCM 311 that is in solid form toward the electronic device 302 whereupon heat of the electronic device 302 liquifies proximal PCM 311 and, at the same time, continuously and repetitively forces the portion 311₂ of the PCM 311 that is in liquid form away from the electronic device 302 for solidification of the PCM 311.

In accordance with embodiments and, as shown in FIGS. 3A and 3B, the spiral actuator 320 can include or be provided as a single-phase spiral actuator 320₁. The single-phase spiral actuator 320₁ has a rotation axis 321 and a single, unitary fin 322 with a leading edge 323, a trailing edge 324 and a body 325 that is disposed between the leading edge 323 and the trailing edge 324. The body 325 forms a ramp curvature about the rotation axis 321 from the leading edge 323 to the trailing edge 324. In these or other cases, as the single-phase spiral actuator 320₁ is rotated by the drive element 330 about the rotation axis 321, the trailing edge 324 and the portion of the body 325 proximate to the trailing edge 324 force the portion 311₁ of the PCM 311 that is in solid form downwardly toward the lower surface 312 and the electronic device 302 while the leading edge 323 and the portion of the body 325 that is proximate to the leading edge 323 force the portion 311₂ of the PCM 311 that is in liquid form outwardly toward the sidewalls 313 and upwardly along the sidewalls 313 for PCM 311 solidification.

In accordance with embodiments and, as shown in FIG. 4, the spiral actuator 320 can include or be provided as a dual-phase spiral actuator 320₂ for use in the system 301 of FIGS. 3A and 3B. The dual-phase spiral actuator 320₂ has a rotation axis 326, a first fin 327 and a second fin 328. The first fin 327 and the second fin 328 are configured similarly as the single, unitary fin 322 of FIGS. 3A and 3B but with opposing ramp curvature pitches. In these or other cases, as the dual-phase spiral actuator 320₂ is rotated by the drive element 330 (see FIGS. 3A and 3B) about the rotation axis 326, the first fin 327 would force the portion 311₁ of the PCM 311 that is in solid form downwardly toward the lower surface 312 and the electronic device 302 while the second fin 328 would force the portion 311₂ of the PCM 311 that is in liquid form outwardly toward the sidewalls 313 and upwardly along the sidewalls 313 for PCM 311 solidification. The dual-phase spiral actuator 320₂ can further include a partition 329 to separate the opposing ramp curvature pitches of the first fin 327 and the second fin 328.

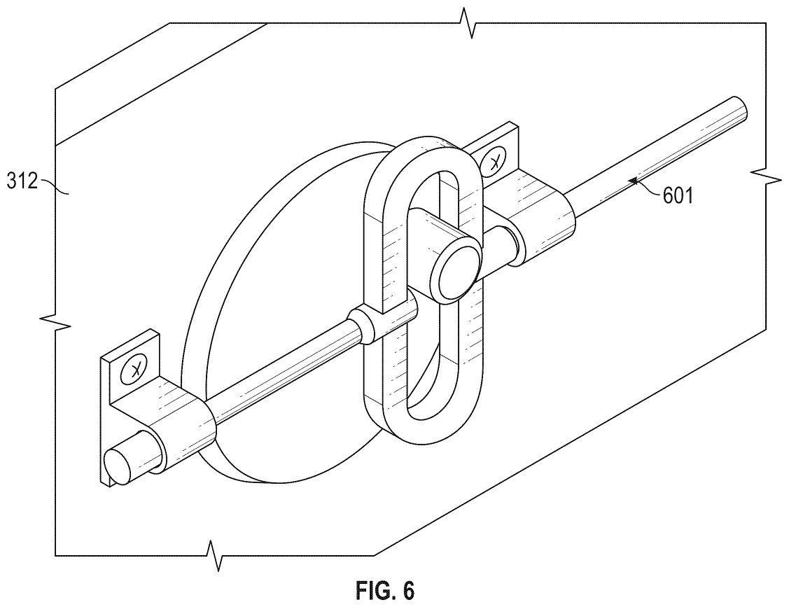

In accordance with embodiments and, as shown in FIG. 5, the spiral actuator 320 can include or be provided as a dual-phase spiral actuator 320₃ with multiple opposing spiral screws (i.e., first spiral screw 341 and second spiral screw 342) for use in the system 301 of FIGS. 3A and 3B. The first and second spiral screws 341 and 342 of the dual-phase spiral actuator 320₃ have a common rotation axis 343 and are each configured similarly as the single, unitary fin 322 of FIGS. 3A and 3B but with opposing screw configurations. In these or other cases, as the first and second spiral screws 341 and 342 of the dual-phase spiral actuator 320₃ are each rotated by the drive element 330 about the common rotation axis 343, the first spiral screw 341 would force the portion 311₁ of the PCM 311 that is in solid form downwardly toward the lower surface 312 and the electronic device 302 while the second spiral screw 342 would force the portion 311₂ of the PCM 311 that is in liquid form outwardly toward the sidewalls 313 and upwardly along the sidewalls 313 for PCM 311 solidification. The dual-phase spiral actuator 320₃ can further include a partition 344 to separate the opposing screw configurations of the first spiral screw 341 and the second spiral screw 342.

The drive element 330 can include or be provided as at least one or more of a stepper motor and a printed circuit board (PCB) motor and/or a shape-memory alloy spring where the shape-memory alloy spring is a torsional spring and the shape-memory alloy spring includes an axial-to-rotational movement mechanism 601 (see FIG. 6). In any case, the rotation of the spiral actuator 320 can be one of discrete (i.e., the rotation rotates by a predetermined angular value, stops and restarts repeatedly) and continuous (i.e., the rotation rotates continuously).

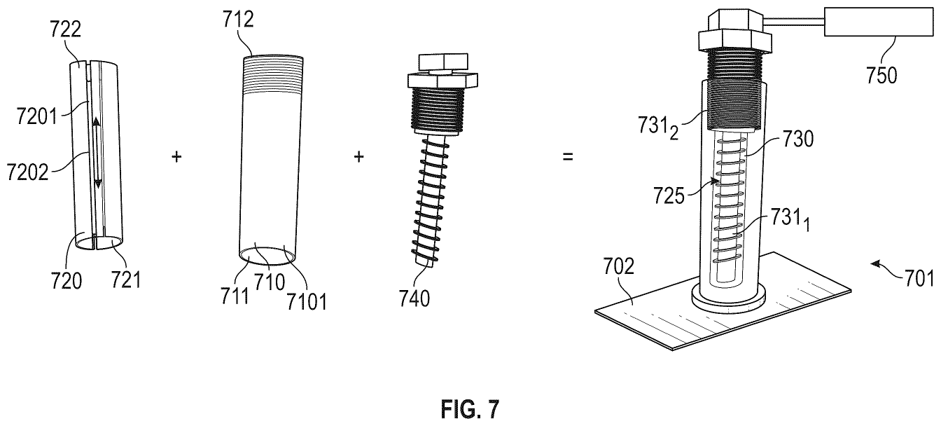

With reference to FIGS. 7-11, a system 701 is provided for heat transfer for an electronic device 702. The system 701 includes an outer container 710, which can be but is not required to be cylindrical, and an inner container 720, which can be but is not required to be cylindrical, and which is disposed within the outer container 710 to define an annular space 725 between an exterior surface 7201 of the inner container 720 and an interior surface 7101 of the outer container 710. For purposes of clarity and brevity, the outer container 710 and the inner container 720 will be described as cylindrical and coaxial, but it is to be understood that this is not required and that other configurations and arrangements are possible.

The outer container 710 has a first end 711 that can be disposed proximate to the electronic device 702 and a second end 712 opposite the first end 711 and the inner container 720 has a first end 721 that can be disposed proximate to the electronic device 702 and a second end 722 opposite the first end 721. The inner container 720 is shorter than the outer container 710 such that the first end 721 of the inner container 720 is slightly higher than the first end 711 of the outer container 710 to allow for flow of liquified PCM beneath the first end 721 of the inner container 720 and such that the second end 722 of the inner container 720 is lower than the second end 712 of the outer container 710 to allow for overflow of the liquified PCM over the second end 722 of the inner container 720.

The system 701 further includes PCM 730 that overfills the inner container 720 above the second end 722 of the inner container 720 and that at least partially fills the outer container 710 in solid or liquid form, an auger or screw (hereinafter referred to as a “screw”) 740 that is disposed in the inner container 720 and a drive element 750. The drive element 750 is coupled with the screw 740 and is configured to drive rotation of the screw 740 to continuously and repetitively force corresponding movements of the portion 731₁ of the PCM 730 that is in solid form and the portion 731₂ of the PCM 730 that is in liquid form. That is, the rotation of the screw 740 continuously and repetitively forces the portion 731₁ of the PCM 730 that is in solid form downwardly through the inner container 720 and toward the electronic device 702 whereupon heat of the electronic device 702 liquifies proximal PCM 730 and, at the same time, continuously and repetitively forces the portion 731₂ of the PCM 730 that is in liquid form upwardly through the annular space 725 and away from the electronic device 702 for solidification of the PCM 730.

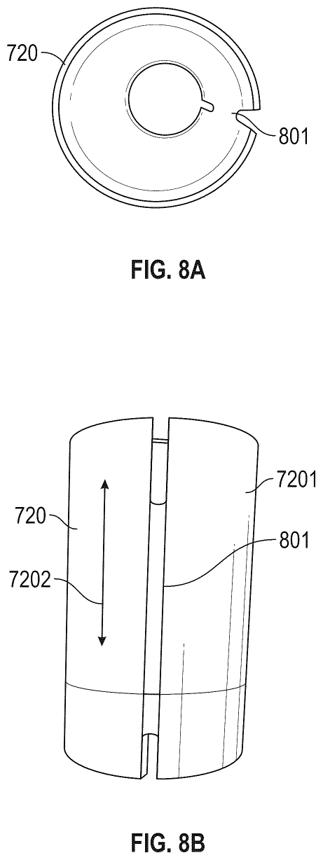

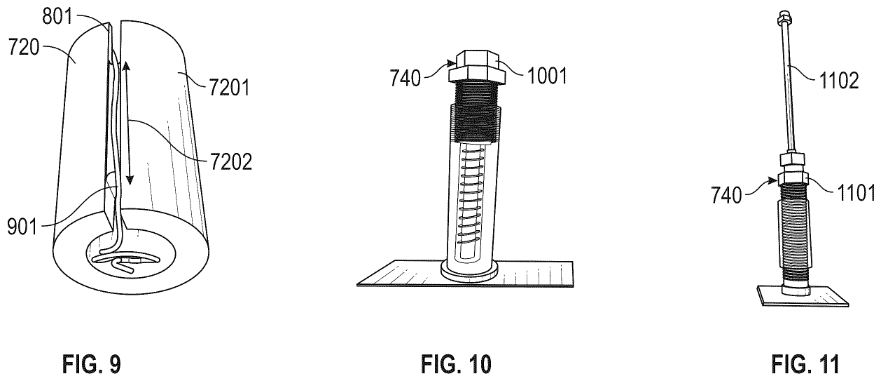

As shown in FIGS. 8A and 8B, the exterior surface 7201 of the inner container 720 can include one or more grooves 801 through which the portion 731₂ of the PCM 730 that is in liquid form can flow while being forced away from the electronic device 702. In accordance with embodiments, the one or more grooves 801 can extend along a longitudinal axis 7202 of the inner container 720. As shown in FIG. 9, the system 701 can further include a heating element 901, such as a copper wire, which is disposed in the one or more grooves 801 to maintain the PCM in liquid form. The heating element 901 can be heated by being disposed in thermal contact with the electronic device 702 and/or can be heated by an external heat source. In any case, the one or more grooves 801 with or without the heating element 901 are configured to maintain a liquified state of the portion 731₂ of the PCM 730 that is in liquid form at least until the PCM 730 is able to flow over the second end 722 of the inner container 720 and into an interior of the inner container 720. The presence of the heating element 901 in the one or more grooves 801 aids in this liquid state maintenance.

As shown in FIG. 10, the screw 740 can include or be provided as a single, monolithic member 1001 that is rotated as one single monolithic element by the drive element 750. As shown in FIG. 11, the screw 740 can include or be provided as a non-rotating portion 1101 and a rotating portion 1102 that extends through the non-rotating portion 1101 and that is rotated by the drive element 750 while the non-rotating portion 1101 is static.

Technical effects and benefits of the present disclosure are the provision of systems and methods for dynamic PCM usage for heat removal from electronic devices. The systems and methods effectively add to the reliability of the electronic devices as the phase change process of the PCM dampens sudden temperature spikes.

The term “about” is intended to include the degree of error associated with measurement of the particular quantity based upon the equipment available at the time of filing the application. For example, “about” can include a range of ±8% or 5%, or 2% of a given value.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

What is claimed is:

1. A system for heat transfer for an electronic device, the system comprising:
a container;
phase change material (PCM) at least partially filling the container in solid or liquid form;
a screw disposed in the container; and
a drive element coupled with the screw and configured to drive screw rotation to continuously and repetitively force:
the PCM in solid form through the container toward the electronic device whereupon electronic device heat liquifies proximal PCM, and
the PCM in liquid form along an exterior of the container away from the electronic device for PCM solidification.

2. The system according to claim 1, wherein the container is cylindrical.

3. The system according to claim 1, wherein the exterior of the container comprises one or more grooves through which the PCM in liquid form is forced away from the electronic device.

4. The system according to claim 3, wherein the one or more grooves extend along a longitudinal axis of the container.

5. The system according to claim 3, further comprising a heating element disposed in the one or more grooves to maintain the PCM in liquid form.

6. The system according to claim 3, further comprising a copper wire disposed in thermal contact with the electronic device and in the one or more grooves to maintain the PCM in liquid form.

7. The system according to claim 1, wherein at least one of:
the screw is a single, monolithic member rotated by the drive element, and
the screw comprises a non-rotating portion and a rotating portion which extends through the non-rotating portion and which is rotated by the drive element.

8. A system for heat transfer for an electronic device, the system comprising:
an outer container;
an inner container disposed within the outer container;
phase change material (PCM) overfilling the inner container and at least partially filling the outer container in solid or liquid form;
a screw disposed in the inner container; and
a drive element coupled with the screw and configured to drive screw rotation to continuously and repetitively force:
the PCM in solid form through the inner container toward the electronic device whereupon electronic device heat liquifies proximal PCM, and
the PCM in liquid form between the inner and outer containers away from the electronic device for PCM solidification.

9. The system according to claim 8, wherein the outer container and the inner container are cylindrical.

10. The system according to claim 8, wherein the inner container comprises one or more grooves on an exterior surface thereof through which the PCM in liquid form is forced away from the electronic device.

11. The system according to claim 10, wherein the one or more grooves extend along a longitudinal axis of the inner container.

12. The system according to claim 10, further comprising a heating element disposed in the one or more grooves to maintain the PCM in liquid form.

13. The system according to claim 10, further comprising a copper wire disposed in thermal contact with the electronic device and in the one or more grooves to maintain the PCM in liquid form.

14. The system according to claim 8, wherein at least one of:
the screw is a single, monolithic member rotated by the drive element, and
the screw comprises a non-rotating portion and a rotating portion which extends through the non-rotating portion and which is rotated by the drive element.

15. A system for heat transfer for an electronic device, the system comprising:
an outer container, which is cylindrical;
an inner container, which is cylindrical and disposed within the outer container to define an annular space between the inner and outer containers;
phase change material (PCM) overfilling the inner container and at least partially filling the outer container in solid or liquid form;
a screw disposed in the inner container; and
a drive element coupled with the screw and configured to drive screw rotation to continuously and repetitively force:
the PCM in solid form through the inner container toward the electronic device whereupon electronic device heat liquifies proximal PCM, and
the PCM in liquid form through the annular space away from the electronic device for PCM solidification.

16. The system according to claim 15, wherein the inner container comprises one or more grooves on an exterior surface thereof through which the PCM in liquid form is forced away from the electronic device.

17. The system according to claim 16, wherein the one or more grooves extend along a longitudinal axis of the inner container.

18. The system according to claim 16, further comprising a heating element disposed in the one or more grooves to maintain the PCM in liquid form.

19. The system according to claim 16, further comprising a copper wire disposed in thermal contact with the electronic device and in the one or more grooves to maintain the PCM in liquid form.

20. The system according to claim 15, wherein at least one of:
the screw is a single, monolithic member rotated by the drive element, and
the screw comprises a non-rotating portion and a rotating portion which extends through the non-rotating portion and which is rotated by the drive element.
